(19) United States
(12) Patent Application Publication
(10) Pub. No.: US 2017/0141792 A1
(43) Pub. Date: May 18, 2017

(54) SWITCH-SCANNING CIRCUIT AND METHOD THEREOF

(71) Applicant: Nuvoton Technology Corporation, Hsinchu (TW)

(72) Inventor: Joseph CHOU, Hsinchu (TW)

(21) Appl. No.: 15/208,597

(22) Filed: Jul. 12, 2016

(30) Foreign Application Priority Data
Nov. 17, 2015 (TW) 104137898

(51) Int. Cl. H03M 11/20; H03K 17/967

(52) U.S. Cl. CPC H03M 11/20; H03K 17/967

(57) ABSTRACT

A switch-scanning circuit includes a chip and switching units. The chip includes pins having an output operation mode and an input operation mode, and a processing unit. The processing unit sets one of the pins as an input pin and the rest of the pins as output pins sequentially according to a clock signal, uses a scan signal to provide different voltages to the output pins, and then determines states of button switches according to a voltage of the input pin. The switching unit includes a power source resistance, switches and resistors. A first terminal and a second terminal of the power source resistance are electrically connected to a power source and a first pin respectively. The resistors have terminals electrically connected the first pin and terminals of the switches. The other terminals of the switches are connected to the pins other than the first pin.

This application claims priority to Taiwanese Application Serial Number 104137898, filed Nov. 17, 2015, which is herein incorporated by reference.

### BACKGROUND

Field of Invention

The present disclosure relates to a scanning circuit and method. More particularly, the present disclosure relates to a switch-scanning circuit and method thereof which determine the state of switches.

Description of Related Art

With the rapid advance of technology, electronic devices are playing an increasingly important role in the lives of many people. When a user operates or interacts with an electronic device, a keypad having a plurality of buttons is a commonly used input tool.

Generally speaking, the buttons on a keypad are connected respectively to switches, and a switching circuit is used to determine whether each switch is switched on or switched off, so as to perform detection with respect to which of the button on the keypad is pressed by the user. Traditionally, there are two kinds of switching circuits used for determining which button is pressed on the keypad. The first kind of switching circuit is a general purpose input/output key matrix circuit in which the buttons are arranged in a matrix, and rows and columns of the buttons in the matrix are respectively connected to general purpose input/output (GPIO) pins of a chip. This arrangement supports composite key input, but occupies many input/output pins and increases the area of a processing chip. The second kind of switching circuit is an analog-to-digital convertor (ADC) key circuit, in which several switching buttons are coupled in parallel with each other, and a pin is used to detect a divided voltage and determine which switching button has been pressed. This arrangement uses just one pin, but does not support composite key input. Furthermore, since the ADC key circuit employs analog techniques, high costs result from encapsulating circuits, making such a configuration unacceptable for most applications.

### SUMMARY

An aspect of the present disclosure is directed to a switch-scanning circuit. The switch-scanning circuit comprises a chip and N switching units. The chip comprises N pins and a processing unit. Each of the pins comprises an output operation mode and an input operation mode. The processing unit is configured to set one of the pins as an input pin and the rest of the pins as output pins sequentially in accordance with a clock signal, and further configured to use a scan signal to provide different voltages to the output pins and determine states of button switches in accordance with a voltage of the input pin. Each of the switching units comprises a power source resistance, M switches and M resistors. A first terminal of the power source resistance is electrically connected to a power source, and a second terminal of the power source resistance is electrically connected to a first pin of the pins. Each of the M resistors has one terminal electrically connected to the first pin, and the other terminal of each of the M resistors is electrically connected to one terminal of one of the M switches, and the other terminal of each of the M switches is connected to one of the pins other than the first pin. Furthermore, the button switches comprise the M switches, N is a positive integer which is greater than or equal to 3, and M is a positive integer which is greater than or equal to 2.

Another aspect of the present disclosure is directed to a switch-scanning circuit. The switch-scanning circuit comprises a chip, a first switching unit, a second switching unit, and a third switching unit. The chip comprises a processing unit, a first pin, a second pin and a third pin, and the processing unit is electrically connected to the pins. The first switching unit comprises a first resistor, a first switch, and a second switch. The first resistor is located between the first pin and a power source, the first switch and a second resistor are located between the first pin and the second pin and coupled with each other in series and, and the second switch and a third resistor are located between the first pin and the third pin and coupled with each other in series. The second switching unit comprises a fourth resistor, a third switch and a fourth switch. The fourth resistor is located between the second pin and the power source, the third switch and a fifth resistor are located between the second pin and the first pin and coupled with each other in series, and the fourth switch and a sixth resistor are located between the second pin and the third pin and coupled with each other in series. The third switching unit comprises a seventh resistor, a fifth switch and a sixth switch. The seventh resistor is located between the third pin and the power source, the fifth switch and an eighth resistor are located between the third pin and the first pin and coupled with each other in series, and the sixth switch and a ninth resistor are located between the third pin and the second pin and coupled with each other in series. Furthermore, the processing unit is configured to set one of the pins as an input pin and the rest of the pins as output pins sequentially in accordance with a clock signal. The processing unit is further configured to use a scan signal to provide different voltages to the output pins and determine states of the switches in accordance with a voltage of the input pin.

Again another aspect of the present disclosure is directed to a switch-scanning method. The switch-scanning method comprises setting one of a plurality of pins as an input pin and the rest of the pins as output pins in accordance with a clock signal; using a scan signal to provide a low electrical potential to an output pin which is scanned and a high electrical potential to the rest of the output pins, wherein the output pin which is scanned is one of the output pins; and determining a state of at least one first switch in accordance with a voltage of the input pin, and the at least one first switch is a switch being one of a plurality of switches and located between the input pin and the output pin which is scanned.

It is to be understood that the foregoing general description and the following detailed description are by examples, and are intended to provide further explanation of the invention as claimed.

### BRIEF DESCRIPTION OF THE DRAWINGS

The present disclosure can be more fully understood by reading the following detailed description of the embodiment, with reference made to the accompanying drawings as follows:

FIGS. 1A-1D are schematic diagrams of a switch-scanning circuit according to some embodiments of the present disclosure;

FIGS. 2A and 2B are schematic diagrams of the switch-scanning circuit according to some embodiments of the present disclosure; and

FIGS. 3A and 3B are flow charts of a switch-scanning method according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

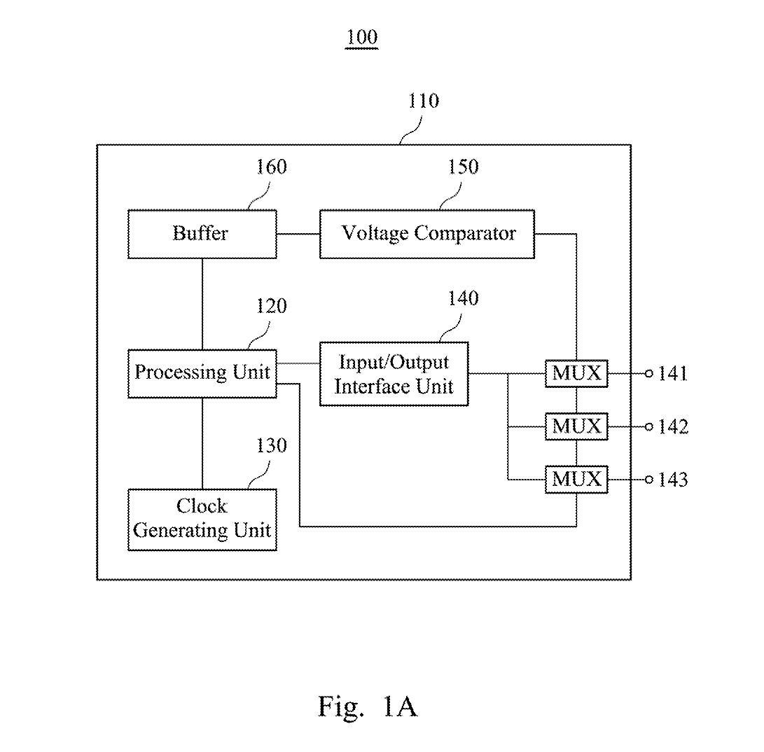

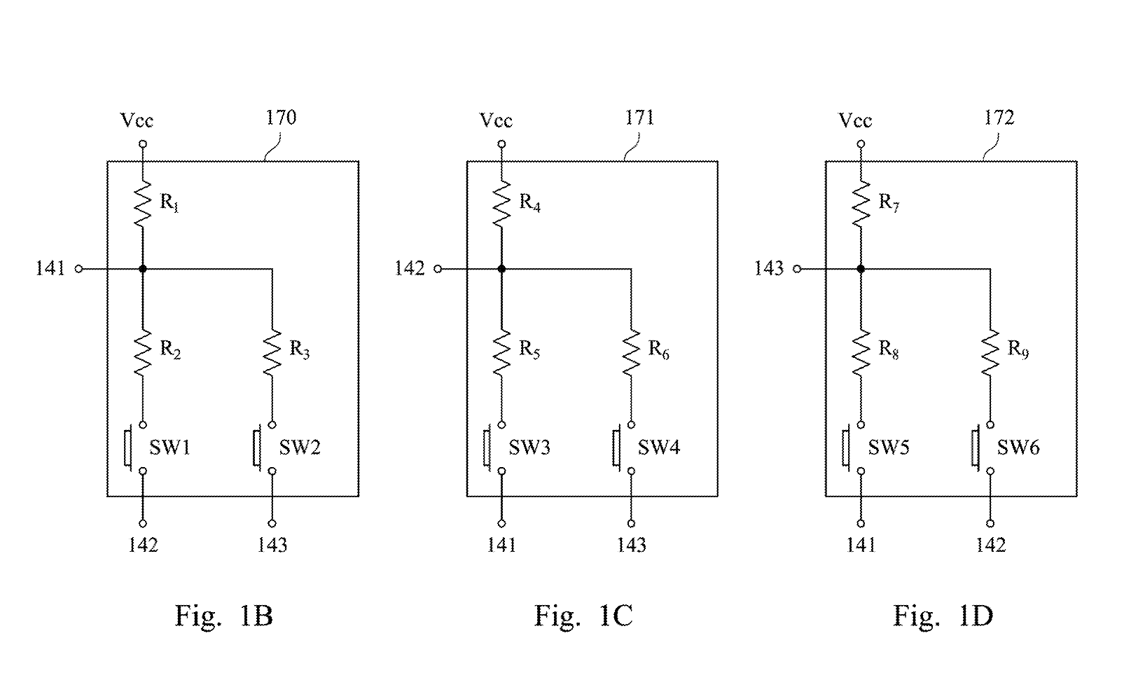

The present disclosure is a switch-scanning circuit configured to determine states of several switches which are connected to buttons to detect the buttons that have been pressed by a user and execute corresponding operations. One embodiment of the switch-scanning circuit in the present disclosure is shown in FIGS. 1A-1D. A switch-scanning circuit 100 includes a chip 110, a first switching unit 170, a second switching unit 171 and a third switching unit 172. The chip 110 includes a processing unit 120, a first pin 141, a second pin 142 and a third pin 143, and the processing unit 120 is electrically connected to the pin 141˜the pin 143. The first switching unit 170 includes a first resistor R1, a first switch SW1 and a second switch SW2. The first resistor R1 is located between the first pin 141 and a power source Vcc, the first switch SW1 and a second resistor R2 are located between the first pin 141 and the second pin 142 and coupled with each other in series, and the second SW2 and a third resistor R3 are located between the first pin 141 and the third pin 143 and coupled with each other in series. The second switching unit 171 includes a fourth resistor R4, a third switch SW3 and a fourth switch SW4. The fourth resistor R4 is located between the second pin 142 and the power source Vcc, the third switch SW3 and a fifth resistor R5 are located between the second pin 142 and the first pin 141 and coupled with each other in series, and the fourth switch SW4 and a sixth resistor R6 are located between the second pin 142 and the third pin 143 and coupled with each other in series. The third switching unit 172 includes a seventh resistor R7, a fifth switch SW5 and a sixth switch SW6. The seventh resistor R7 is located between the third pin 143 and the power source Vcc, the fifth switch SW5 and an eighth resistor R8 are located between the third pin 143 and the first pin 141 and coupled with each other in series, and the sixth switch SW6 and a ninth resistor R9 are located between the third pin 143 and the second pin 142 and coupled with each other in series. The processing unit 120 is configured to set one of the pin 141˜the pin 143 as an input pin and the rest of the pins as output pins sequentially according to a clock signal generated by a clock generating unit 130 through an input/output interface unit 140, and use a scan signal to provide different voltages to the output pins and determine states of the switches SW1˜SW6 according to a voltage of the input pin.

Specifically, after the processing unit 120 sets the first pin 141 as the input pin, the processing unit 120 uses the scan signal to respectively provide the different voltages to the pin 142 and the pin 143 which are set as output pins. Because the switching states of the first switch SW1 and the second switch SW2 in the first switching unit 170 affect the voltage of the input pin, the voltage of the first pin 141 represents a reference to determine the switching states of the first switch SW1 and the second switch SW2. Subsequently, the processing unit 120 sets the second pin 142 as the input pin and uses the scan signal to respectively provide different voltages to the output pin 141 and the output pin 143, and then determines the switching states of the third switch SW3 and the fourth switch SW4 according to a voltage of the second pin 142. Subsequently, the processing unit 120 sets the third pin 143 as the input pin and uses the scan signal to respectively provide different voltages to the output pin 141 and the output pin 142, and then determines the switching states of the fifth switch SW5 and the sixth switch SW6 according to a voltage of the third pin 143. The chip 110 in the switch-scanning circuit 100 is connected to switching units through the pins thereof, and several switches are located in the switching units. Subsequently, the chip 110 sets one of the pins as the input operation mode and rest of the pins as the output operation mode and scans the output pins, so that the switch-scanning circuit 100 can use the limited number of pins to determine states of the switches in the switching units. Because the switches are electrically connected to different buttons respectively, the switch-scanning circuit 100 can determine the buttons pressed by the user according to the states of the switches. Compared with a traditional keypad circuit, the switch-scanning circuit 100 requires fewer pins but supports more buttons and composite key input function, so that hardware costs and an area of the chip are reduced, but a composite key input capability is supported.

The processing unit 120 is a processor having an ARM structure, a microprocessor having MIPS structure or a microcontroller. The clock generating unit 130 is composed of a resonant circuit and an amplifier, and the resonant circuit is implemented according to a Quartz piezo-electric oscillator or a tank circuit. The input/output interface unit 140 is a general purpose input/output (GPIO) interface controller or any other multi-function input/output interface controller. The input/output interface unit 140 is connected to the pin 141˜the pin 143 through a multiplexer to select an output direction of data.

In one embodiment, the processing unit 120 sets the first pin 141 as the input pin, and uses the scan signal to respectively provide the different voltages to the pin 142 and the pin 143. When the second pin 142 is scanned, the processing unit 120 uses the scan signal to provide a low electrical potential to the second pin 142 which is scanned and a high electrical potential to the rest of the output pin(s). In this embodiment, the rest of the output pin(s) is the third pin 143. In other embodiments, if the number of the rest of the output pins is plural, the rest of the output pins are all provided with the high electrical potential. The electrical potential of each of the output pins (i.e., the second pin 142 and the third pin 143) is known, the resistors provided with the high electrical potential can be simplified to an equivalent circuit, so the processing unit 120 determines the state of the first switch SW1 according to the voltage of the input pin (i.e., the first pin 141). When the pin 143 is scanned, the processing unit 120 uses the scan signal to provide the low electrical potential to the pin 143 which is scanned and the high electrical potential to the rest of the output pins (i.e., the pin 142) to determine the state of the second switch SW2. Furthermore, the low electrical potential is a ground voltage, and the high electrical potential is a voltage of the power source Vcc. After the processing unit 120 uses the scan signal to respectively provide the different voltages to the second pin 142 and the third pin 143 in sequential order, it is finished determining the states of the first switch SW1 and the second switch SW2 in the first switching unit 170, and similar operations are executed for the second switching unit 171 and the third switching unit 172 to determine states of the third switch SW3˜the sixth switch SW6.

Specifically, when the processing unit 120 sets the pin 141 as the input pin, and uses the scan signal to provide the low electrical potential to the output pin 142 which is scanned and the high electrical potential to the pin 143, circuits of the first switching unit 170, the second switching unit 171 and the third switching unit 172 can be simplified, so that the first switch SW1 and the second resistor R2 in series arrangement and the third switch SW3 and the fifth resistor R5 in series arrangement are arranged between the first pin 141 and the second pin 142 in parallel, and the first resistor R1 is located between the first pin 141 and the power source Vcc. The processing unit 120 determines the state of the first switch SW1 according to the voltage of the input pin 141. When the voltage of the input pin 141 is close to the voltage of the power source Vcc, the processing unit 120 determines that it is open between the first pin 141 and the second pin 142, and determines that the state of first switch SW1 is switched off. When a ratio of the voltage of the input pin 141 to the voltage of the power source Vcc is close to a ratio of the resistance of the second resistor R2 to the resistance of the first resistor R1 plus the second resistor R2, this indicates that the voltage of the input pin (i.e., the first pin 141 in this embodiment) is a divided voltage which is generated by dividing the voltage of the power source Vcc through the first resistor R1 and the second resistor R2. Therefore, the processing unit 120 determines that the state of the first switch SW1, which is connected with the second resistor R2 in series and located between the first pin 141 and the second pin 142, is switched on.

Furthermore, when the processing unit 120 sets the pin 141 as the input pin, and uses the scan signal to provide the low electrical potential to the output pin 143 which is scanned and the high electrical potential to the pin 142, the circuits of the first switching unit 170, the second switching unit 171 and the third switching unit 172 can be simplified, so that the second switch SW2 and the third resistor R3 in series arrangement and the fifth switch SW5 and the eighth resistor R8 in series arrangement are arranged between the first pin 141 and the third pin 143 in parallel, and the first resistor R1 is located between the first pin 141 and the power source Vcc. The processing unit 120 determines the state of the second switch SW2 according to the voltage of the input pin 141. When the voltage of the input pin 141 is close to the voltage of the power source Vcc, the processing unit 120 determines that there is an open circuit between the first pin 141 and the second pin 143, and further determines that the state of the second switch SW2 is off. When the ratio of the voltage of the input pin 141 to the voltage of the power source Vcc is close to a ratio of the resistance of the third resistor R3 to the resistance of the first resistor R1 plus the third resistor R3, this indicates that the voltage of the input pin (i.e., the first pin 141 in this embodiment) is a divided voltage which is generated by dividing the voltage of the power source Vcc through the first resistor R1 and the third resistor R3. Therefore, the processing unit 120 determines that the state of the second switch SW2, which is arranged with the third resistor R3 in series and located between the first pin 141 and the second pin 143, is on.

In one embodiment, the different switches (e.g., the first switch SW1, the second switch SW2 and the third switch SW3) can be switched on at the same time. Specifically, when the processing unit 120 sets the pin 141 as the input pin, and uses the scan signal to provide the low electrical potential to the output pin 142 which is scanned and the high electrical potential to the pin 143, the states of the first switch SW1 and the third switch SW3 have four conditions as described below. Firstly, when the voltage of the first pin 141 is equal to 0, it is necessary to scan the state of third switch SW3 to determine the state of the first switch SW1, and if the voltage of the second pin 142 also is equal to 0 while the third switch SW3 is being scanned, it is determined that the first switch SW1 and the third switch SW3 both are switched on at the same time. Secondly, when the voltage of the first pin 141 is close to the voltage of the power source Vcc multiplied by a ratio of the resistance of the second resistor R2 to the resistance of the first resistor R1 plus the second resistor R2, it is determined that the state of the first switch SW1 is on, and the state of the switch SW3 is off. Thirdly, when the voltage of the first pin 141 is equal to 0 and the voltage of the second pin 142 is equal to the voltage of the power source Vcc multiplied by a ratio of the resistance of the fifth resistor R5 to the resistance of the fourth resistor R4 plus the fifth resistor R5 while the third switch SW3 is being scanned, it is determined that the state of the first switch SW1 is off, and the state of the third switch SW3 is on. Fourthly, when the voltage of the first pin 141 is equal to the voltage of the power source Vcc, it is determined that the states of the first switch SW1 and the third switch SW3 are switched off at the same time.

In practice, the first switch SW1 and the second switch SW2 can be switched on at the same time. Specifically, when the voltage of the first pin 141 is equal to the voltage of the power source Vcc multiplied by a ratio of the resistance of the second resistor R2 to the resistance of the first resistor R1 and the third resistor R3 in parallel arrangement plus the second resistor R2, it can be determined that the first switch SW1 and the second switch SW2 are switched on at the same time. Furthermore, if the resistance of the first resistor R1, the second resistor R2 and the third resistor R3 are the same, the voltage of the power source Vcc multiplied by the ratio of the resistance of the second resistor R2 to the resistance of the first resistor R1 and the third resistor R3 in parallel arrangement plus the second resistor R2 must be smaller than the voltage of the power source Vcc multiplied by the ratio of the resistance of the second resistor R2 to the resistance of the first resistor R1 plus the second resistor R2. Table 1 and Table 2 show the states of the first switch SW1, the second switch SW2 and the third switch SW3 corresponding to the different voltages of the first pin 141.

TABLE 1
The states of the first switch and the third switch
corresponding to the voltage of the first pin

Index of the switch

| Voltage of | The first switch | The third switch |
|---|---|---|
| the first pin | SW1 | SW3 |
| 0 | Switched on | Switched on |
| Vcc · R2/(R1 + R2) | Switched on | Switched off |
| 0 | Switched off | Switched on |
| Vcc | Switched off | Switched off |

TABLE 2
The states of the first switch and the second switch
corresponding to the voltage of the first pin

| | Index of the switch | |
|---|---|---|
| Voltage of | The first switch | The second switch |
| the first pin | SW1 | SW2 |
| Vcc · R2/((R1//R3) + R2) | Switched on | Switched on |

Furthermore, when the processing unit 120 sets the pin 141 as the input pin, and uses the scan signal to provide the low electrical potential to the output pin 143 which is scanned and the high electrical potential to the pin 142, the states of the second switch SW2 and the rest of the switches can be analyzed as illustrated above.

In one embodiment, the chip 110 in the switch-scanning circuit further includes a buffer 160 and a voltage comparator 150. The buffer 160 is configured to store a high threshold and a low threshold to determine whether the voltage of the pin is close to the voltage of the power source Vcc or the voltage of the power source following voltage division respectively. The voltage comparator 150 is configured to compare the voltage of the input pin with a reference voltage and generate a comparison result. The processing unit 120 modifies the reference voltage of the voltage comparator 150 to the high threshold or the low threshold dynamically, and determines a state of a switch located between the input and the output pin which is scanned according to the comparison result generated from the voltage comparator 150. The switch-scanning circuit 100 uses the voltage comparator 150 to compare the voltage of the pin with the high threshold and the low threshold and determine the states of the switches. Therefore, the hardware costs associated with the analog circuit are reduced, and the switch-scanning circuit is utilized to reduce the number of the input/output pins and determine states of button switches through digital operations economically.

The buffer 160 can be a dynamic random-access memory (DRAM), a static random-access memory (Static RAM), or a flash memory. Persons of ordinary skill in the art can use other types of memory or storage units to implement the buffer 160, and so the buffer 160 is not limited by such examples. The voltage comparator 150 can be a differential amplifier or a CMOS clocked comparator. Persons of ordinary skill in the art can use other circuit units to implement the voltage comparator 150, and so the voltage comparator 150 is not limited by such examples.

In one embodiment, the processing unit 120 sets the input pin as the first pin 141, and sets the second pin 142 as the output pin which is scanned. The processing unit 120 determines the state of the first switch SW1 according to the comparison result from the voltage comparator 150. Subsequently, the processing unit 120 uses the scan signal to respectively provide the different voltage to the third pin 143, and determines the state of the second switch SW2 according to the comparison result from the voltage comparator 150. The processing unit 120 sets the second pin 142 and the third pin 143 as the input pin sequentially, and executes the similar operations to determine the states of the switches in the second switching unit 171 and the third switching unit 172.

In another embodiment, the processing unit 120 sets the input pin as the first pin 141, the second pin 142 as the output pin which is scanned to receive the low electrical potential, and the third pin 143 to receive the high electrical potential. The processing unit 120 sets the reference voltage of the voltage comparator 150 as a first threshold, and then the voltage comparator 150 compares the voltage of the input pin (i.e., the first pin 141) with the reference voltage. When the comparison result shows that the voltage of the input pin is higher than the first threshold, the processing unit 120 determines that the first switch SW1 is switched off. When the comparison result shows that the voltage of the input pin is lower than the first threshold, the processing unit 120 sets the reference voltage of the voltage comparator 150 as a second threshold which is lower than the first threshold, and then the voltage comparator 150 compares the voltage of the input pin (i.e., the first pin 141) with the reference voltage. When the comparison result shows that the voltage of the input pin is higher than the second threshold, the processing unit 120 determines that the first switch SW1 is switched on. When the comparison result shows that the voltage of the input pin (i.e., the first pin 141) is lower than the second threshold, the processing unit 120 sets the reference voltage of the voltage comparator 150 as a third threshold which is lower than the second threshold, and the voltage comparator 150 then compares the voltage of the input pin (i.e., the first pin 141) with the reference voltage. When the comparison result shows that the voltage of the input pin is higher than the third threshold, the processing unit 120 determines that the first switch SW1 is switched on. When the comparison result shows that the voltage of the input pin (i.e., the first pin 141) is lower than the third threshold, the first switch SW1 and the third switch SW3 between the input pin (i.e., the first pin 141) and the output pin which is scanned (i.e., the second pin 142) can be switched on at the same time, or only the third switch SW3 is switched on. Therefore, the processing unit 120 records the comparison result and the state of the first switch SW1 in the buffer 160, and sets the second pin 142 as the input pin to determine the state of the first switch SW1 and the third switch SW3 according to records in the buffer 160 and the comparison results from the voltage comparator 150 when the first pin 141 is scanned. Specifically, when the second pin 142 is the input pin and the first pin 141 is the output pin which is scanned, and when the comparison result from the voltage comparator 150 shows that the voltage of the second pin 142 is lower than the first threshold and higher than the second threshold, the processing unit 120 determines that the third switch SW3 is switched on, and also determines that the first switch SW1 is switched off according to the records in the buffer 160. When the comparison result from the voltage comparator 150 shows that the voltage of the second pin 142 is lower than the second threshold, the processing unit 120 determines that the first switch SW1 and the third switch SW3 are switched on at the same time according to the records in the buffer 160. The operation related to the rest of the switches may be deduced by analogy. After the processing unit 120 sets the first pin 141 the third pin 143 as the input pin sequentially, and uses the scan signal to provide a different voltage to all of the output pins, the states of the switches SW1˜SW6 are determined, and composite key input is supported.

In one embodiment, the high threshold and the low threshold are related to the resistance of the first resistor R1˜the ninth resistor R9. For example, when the voltage of the power source Vcc is 3.3V, the resistance of each of the first resistor R1˜the ninth resistor R9 is 100 kΩ, the switches SW1˜SW6 in the switch-scanning circuit are switched on at the same time, resistors which are arranged with the switches SW1˜SW6 in series respectively are arranged in parallel with each other, and the resistors are arranged with other resistors which are located between the input pin and the power source in series. The voltage of the input pin is 2.82V. Therefore, the high threshold has to be close to the voltage of the power source Vcc and higher than 2.82V, so that it is set as 3V in this embodiment. Furthermore, a ratio between the first resistor R1 and the second resistor R2 is 1:1. Therefore, the low threshold must be lower than 1.65V which is half of the voltage of the power source Vcc, and it is set as 1V in this embodiment. Persons of ordinary skill in the art can modify the high threshold and the low threshold depending on the specific resistances of the resistors which are used after reading the present disclosure, so that the high threshold and the low threshold are not limited by the example given herein.

In another embodiment, because the high electrical potential and the low electrical potential provided from the chip 110 through the scan signal have some deviation, when the resistance of the resistors in the first switching unit 170˜the third switching unit 172 are the same, the high threshold is equal to the voltage of the power source Vcc minus a range value, and the low threshold is equal to half of the voltage of the power source Vcc minus another range value. For example, the range value and the other range value are voltages between 0.3V˜0.5V. Persons of ordinary skill in the art can modify the range value and the other range value depending on the specific high electrical potential and low electrical potential provided through the scan signal after reading the present disclosure, so that the high threshold and the low threshold are not limited by the example given herein.

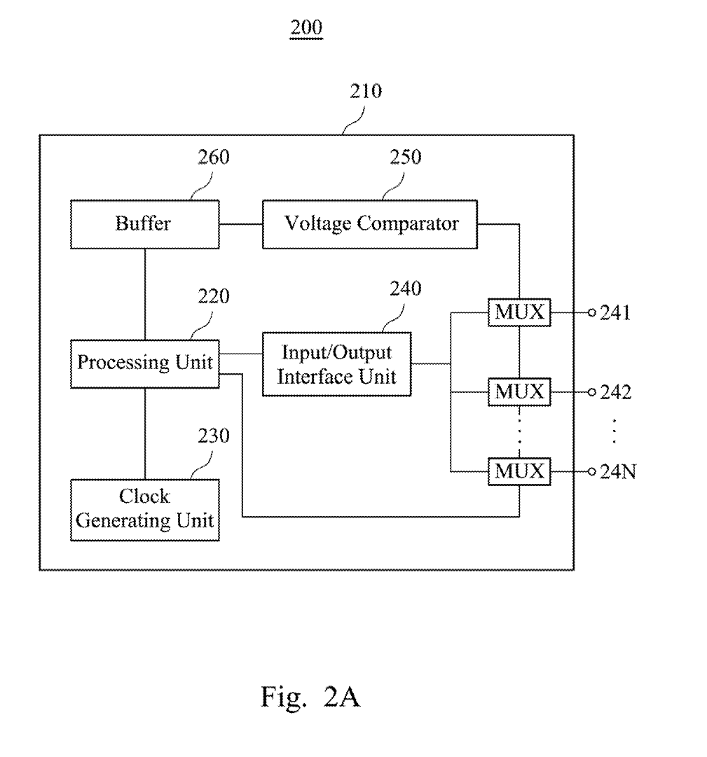

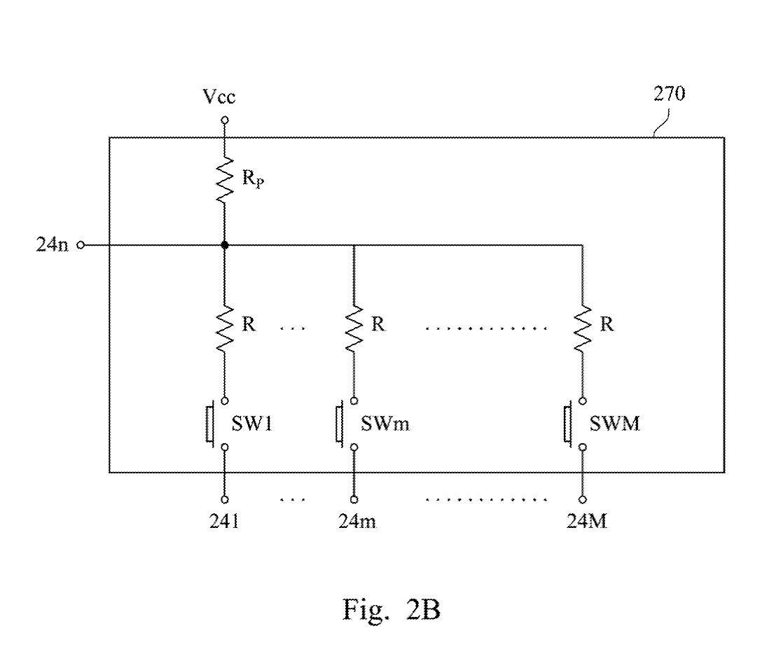

FIGS. 2A and 2B are schematic diagrams of a switch-scanning circuit 200 according to some embodiments of the present disclosure. The switch-scanning circuit 200 includes a chip 210 and N switching units 270, where N is a positive integer greater than or equal to 3. As shown in FIG. 2A, the chip 210 includes N pins (i.e., a pin 241, a pin 242˜a pin 24N), and operation modes of the pin 241˜the pin 24N have an output operation mode and an input operation mode. Each of the pin 241˜the pin 24N of the chip 210 is connected to the switching units 270 as shown in FIG. 28. Each of the switching units 270 includes a power source resistance R_{P}, M switches (i.e., switches SW1˜SWM) and M resistors R, where M is a positive integer greater than or equal to 2 and M is smaller than N. A first terminal of the power source resistance R_{P} in the switching unit 270 is electrically connected to the power source Vcc, a second terminal of the power source resistance R_{P} is connected to a first pin 24n in the pin 241˜the pin 24N of the chip 210. Each of the M resistors R has one terminal electrically connected to the first pin 24n, and the other terminal of each of the M resistors R is electrically connected to one terminal of one of the switches SW1˜SWM, the other terminal of each of the switches SW1˜SWM is connected to one of the pins other than the first pin 24n, and a keyboard switch includes the switches in all of the switching units 270. The first pins 24n which are connected to the switching units 270 are distinct, and n is a positive integer between 1˜N.

According to a clock signal generated from a clock generating unit 230, the processing unit 220 in the chip sets the operation mode of one of the pin 241˜pin 24N to the input operation mode as the input pin sequentially through the input/output interface unit 240, and sets the operation mode of the rest of the pins other than the input pin to the output operation mode as the output pins. The processing unit 220 uses a scan signal to provide different voltages to the output pins, and determines states of several button switches in the switch-scanning circuit 200 according to a voltage of the input pin. The types of elements, the connection among the elements and operations of the elements in the chip 210 and the switching units 270 are similar to those shown in FIG. 1A˜1D. The number of the pins of the chip in the switch-scanning circuit 200 can be increased to support the different number of buttons according to requirements of the application, and the switches SW1˜SWM in the switching unit 270 correspond to different buttons in the keypad respectively. After the switch-scanning circuit 200 sets the pin 241˜the pin 24N as the input pin sequentially, and uses the scan signal to respectively provide the different voltages to the output pins for the input pin, the states of all of the switches are determined, and the composite key input with limited output pins and a low cost is supported.

In one embodiment, the processing unit 220 uses the scan signal to provide a low electrical potential to the output pin which is scanned and a high electrical potential to the rest of the output pins, and determines states of the switches according to the voltage of the input pin. The processing unit 220 uses the scan signal to provide the low electrical potential to each of the output pins sequentially. In other words, the processing unit 220 uses the scan signal to provide different voltages to all of the output pins to finish determining the states of the switches in the switching unit 270 connected to the input pin.

In another embodiment, the chip 210 further includes a buffer 260 and a voltage comparator 250. The buffer 260 is configured to store a high threshold and a low threshold to determine whether the voltage of the input pin is close to the voltage of the power source Vcc or the voltage of the power source Vcc divided through resistors respectively. The voltage comparator 250 is configured to compare the voltage of the input pin with a reference voltage to generate a comparison result. The processing unit 220 modifies the reference voltage of the voltage comparator 250 to the high threshold or the low threshold dynamically, and determines the state of the switch between the input pin and the output pin which is scanned according to the comparison generated from voltage comparator 250. Furthermore, the buffer 260 and the voltage comparator 250 have functions and implementations which are similar to those of the buffer 160 and the voltage comparator 150 respectively.

For example, when the output pin which is scanned is a pin 24m (where m is a positive integer between 1˜N, and m is not equal to n), i.e., the scan signal provides the low electrical potential to the pin 24m, the processing unit 220 determines the state of the switch SWm according to the voltage of the first pin 24n which is set as the input pin, in which a number suffixed after a switch SW indicates a switch located between the input pin 24n and the output pin 24m which is scanned, and the output pins which have to be scanned are the pin 241˜the pin 24M (the number of possibilities of M equals N−1, i.e., the rest of the pin 241˜24N other than the input pin 24n are the output pins). In another embodiment, when the voltage of the input pin 24n is higher than the high threshold, the processing unit 220 determines that the switch SWm between the input pin 24n and the output pin 24m which is scanned is switched off. When the voltage of the input pin 24n is lower than the high threshold and higher than the low threshold, the processing unit 220 determines that the switch SWm is switched on. When the voltage of the input pin 24n is lower than the low threshold, the processing unit 220 records the comparison result and the state of the switch SWm in the buffer 260. After the processing unit 220 sets the pin 241˜the pin 24N as the input pin sequentially, and scans all of the output pins for each of the input pins, the processing unit 220 determines the states of all of the switches in the N switching units 270 according to the voltage of the input pin and the records in the buffer 260.

The high threshold and the low threshold stored in the buffer 260 in the switch-scanning circuit 200 are related to the resistances of the resistors R in the switching unit 270. In one embodiment, the resistances of the resistors R are the same, so that the high threshold is equal to the voltage of the power source Vcc minus a range value, and the low threshold is equal to half of the voltage of the power source Vcc minus another range value. The manner in which the high threshold and the low threshold are calculated according to the resistances of the resistors R and the voltage of the power source Vcc is similar to that described above.

It is noted that M is a positive integer smaller than N in the switch-scanning circuit 200. In other words, when the chip 210 has 4 pins, the switch-scanning circuit 200 supports a determination of states of 4×(4−1) switches at most. For a chip that has N pins, the switch-scanning circuit 200 supports N×(N−1) buttons, and supports the composite key input. Therefore, more buttons are supported with the switch-scanning circuit 200 than with a traditional GPIO button matrix used to support the composite key input.

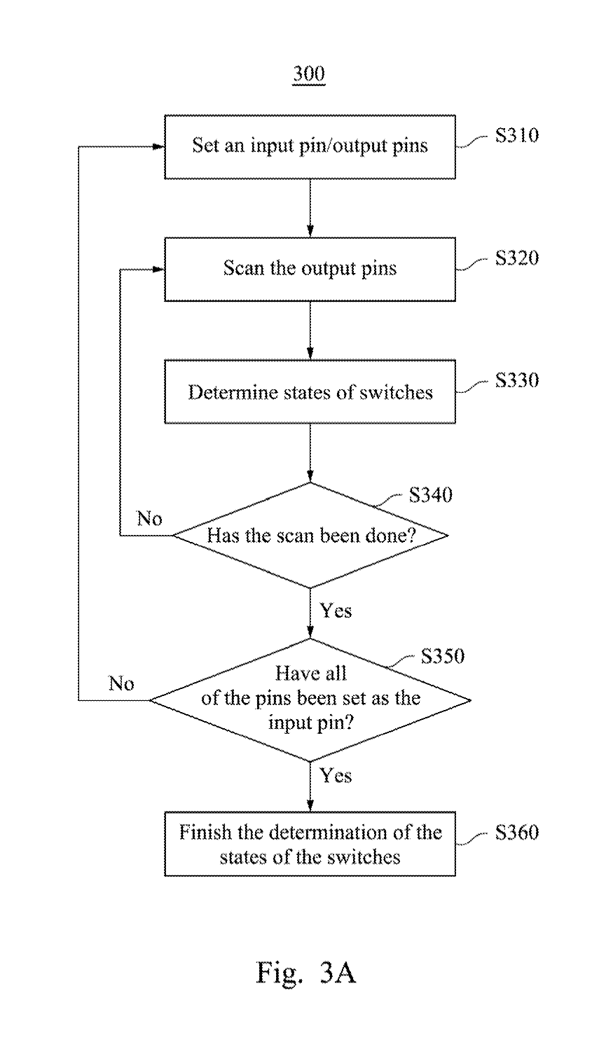

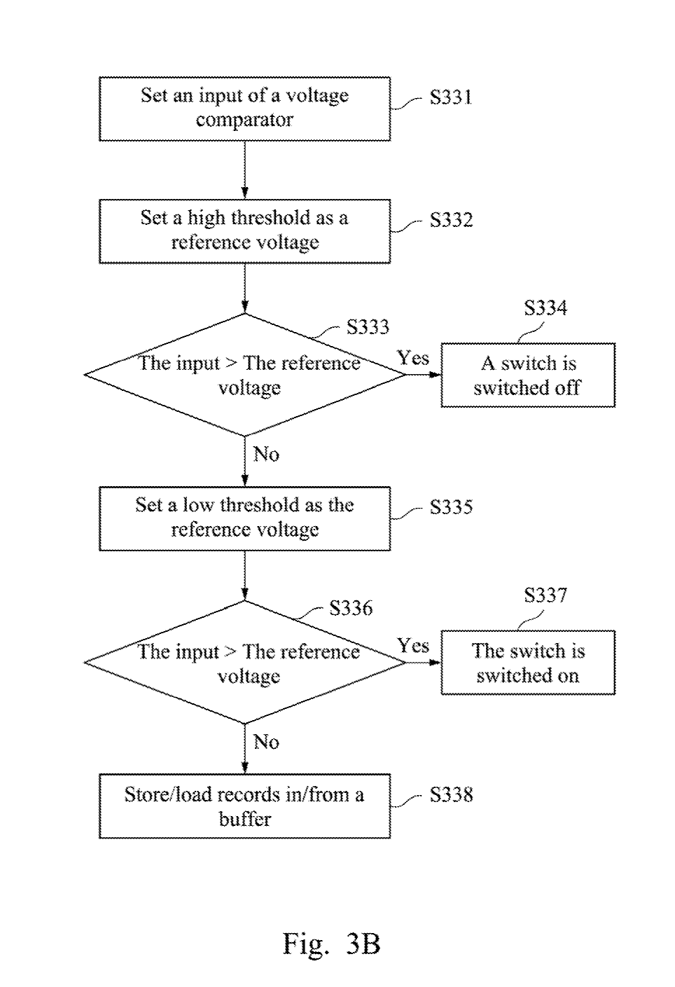

FIGS. 3A and 3B are flow charts of a switch-scanning method according to some embodiments of the present disclosure. For simplify the description to follow and make the same clear, the explanation of the switch-scanning method 300 will be given using the switch-scanning circuit 200 shown in FIG. 2A and FIG. 2B, but the present disclosure is not limited in this regard.

In operation S310, the processing unit 220 sets one of the pin 241˜the pin 24N as the input pin, and sets the rest of the pin 241˜the pin 24N other than the input pin as the output pins according to a dock signal. For the input pin which is set in operation S310, the processing unit 220 scans the output pin (in operation S320). Specifically, the processing unit 220 uses the scan signal to provide the low electrical potential to the output pin which is scanned and the high electrical potential to the rest of the output pins. The processing unit 220 determines the state of the first switch according to the voltage of the input pin (in operation S330). Furthermore, the first switch is one of switches which is located among the pin 241˜the pin 24N, and the first switch is located between the input pin and the output pin which is scanned in switches located among the pin 241˜the pin 24N. For each of the input pins, after the processing unit 220 scans one output pin, the processing unit 220 checks whether some output pins have not been scanned yet (in operation S340). If there are some output pins which have not been scanned, the processing unit 220 continues scanning the next output pin (in operation 320); otherwise, the processing unit 220 checks whether all of the pins have been set as the input pin (in operation S350). If all of the pins have been set as the input pin, the states of all of the switches in the switch-scanning circuit 200 are determined (in operation S360). No matter how many buttons (e.g., a single button or several buttons) which are electrically connected to the switches are pressed by the user, the switch-scanning method 300 can determine the buttons which are pressed by the user.

In one embodiment, the processing unit 220 determines the state of the first switch according to the voltage of the input pin in operation S330. The processing unit 220 compares the voltage of the input pin with a high threshold and a low threshold respectively, and determines the state of the first switch according to the comparison result. For example, the processing unit 220 sets an input voltage of the voltage comparator 250 as the voltage of the input pin (in operation S331), and sets the reference voltage of the voltage comparator 250 as a high threshold (in operation S332). The voltage comparator 250 is configured to determine whether the input voltage is higher or lower than the reference voltage (in operation S333). When the voltage of the input pin is higher than the reference voltage (i.e., the high threshold), the processing unit 220 determines that the first switch is switched off (in operation S334). When the voltage of the input pin is lower than the reference voltage (i.e., the high threshold), the processing unit 220 sets the reference voltage of the voltage comparator 250 as a low threshold (in operation S335). The voltage comparator 250 is configured to determine whether the input voltage is higher or lower than the reference voltage (in operation S336). When the voltage of the input pin is higher than the reference voltage (i.e., the low threshold), the processing unit 220 determines that the first switch is switched on (in operation S337). When the voltage of the input pin is lower than the reference voltage (i.e., the low threshold), the processing unit 220 records the comparison result and the state of the first switch in the buffer 260. After the processing unit 220 sets the pin 241˜the pin 24N as the input pin sequentially, and scans all of the output pins for the input pin, the processing unit 220 loads the records in the buffer 260 and determines the states of all of the switches according to the records (in operation S338).

When a chip includes limited input/output pins, the switch-scanning circuit and method thereof of the present disclosure supports a larger number of buttons than a traditional keyboard switch-scanning circuit, and the cost of hardware encapsulation is reduced, such that composite key input is supported with a low cost of hardware.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present invention cover modifications and variations of this present disclosure provided they fall within the scope of the following claims.

What is claimed is:

1. A switch-scanning circuit, comprising:
a chip comprising:
N pins, each of the pins comprising an output operation mode and an input operation mode; and
a processing unit configured to set one of the pins as an input pin and the rest of the pins as a plurality of output pins sequentially in accordance with a clock signal, and further configured to use a scan signal to provide different voltages to the output pins and determine states of a plurality of button switches in accordance with a voltage of the input pin; and
N switching units, each of the switching units comprising a power source resistance, M switches and M resistors, wherein a first terminal of the power source resistance is electrically connected to a power source, a second terminal of the power source resistance is electrically connected to a first pin of the pins, each of the M resistors has one terminal electrically connected to the first pin, the other terminal of each of the M resistors is electrically connected to one terminal of one of the M switches, and the other terminal of each of the M switches is connected to one of the pins other than the first pin, wherein the button switches comprise the M switches, N is a positive integer which is greater than or equal to 3, and M is a positive integer which is greater than or equal to 2.

2. The switch-scanning circuit of claim 1, wherein the chip further comprises:
a buffer configured to store a high threshold and a low threshold; and
a voltage comparator configured to compare the voltage of the input pin with a reference voltage to output a comparison result, wherein the processing unit modifies the reference voltage to the high threshold or the low threshold dynamically.

3. The switch-scanning circuit of claim 2, wherein one of the switching units is a first switching unit, the processing unit determines a state of a first switch in the first switching unit in accordance with the comparison result, and the first switch is located between the input pin and the output pin which is scanned.

4. The switch-scanning circuit of claim 3, wherein when the voltage of the input pin is higher than the high threshold, the processing unit determines that the first switch is switched off; when the voltage of the input pin is lower than the high threshold and higher than the low threshold, the processing unit determines that the first switch is switched on; and when the voltage of the input pin is lower than the low threshold, the processing unit records the comparison result and the state of the first switch in the buffer.

5. The switch-scanning circuit of claim 2, wherein the high threshold and the low threshold are related to resistances of the resistors.

6. The switch-scanning circuit of claim 2, wherein the resistances of the resistors are the same, the high threshold is equal to a voltage of the power source minus a range value, and the low threshold is equal to half of the voltage of the power source minus another range value.

7. The switch-scanning circuit of claim 1, wherein the processing unit uses the scan signal to provide a low electrical potential to the output pin which is scanned and a high electrical potential to the rest of the output pins.

8. The switch-scanning circuit of claim 1, wherein M is a positive integer which is smaller than N.

9. A switch-scanning circuit, comprising:
a chip comprising a processing unit, a first pin, a second pin and a third pin, and the processing unit is electrically connected to the pins;
a first switching unit comprising:
a first resistor located between the first pin and a power source;
a first switch, the first switch and a second resistor being located between the first pin and the second pin and coupled with each other in series; and
a second switch, the second switch and a third resistor being located between the first pin and the third pin and coupled with each other in series;
a second switching unit comprising:
a fourth resistor located between the second pin and the power source;
a third switch, the third switch and a fifth resistor being located between the second pin and the first pin and coupled with each other in series; and
a fourth switch, the fourth switch and a sixth resistor being located between the second pin and the third pin and coupled with each other in series; and
a third switching unit comprising:
a seventh resistor located between the third pin and the power source;
a fifth switch, the fifth switch and an eighth resistor being located between the third pin and the first pin and coupled with each other in series; and
a sixth switch, the sixth switch and a ninth resistor being located between the third pin and the second pin and coupled with each other in series;
wherein the processing unit is configured to set one of the pins as an input pin and the rest of the pins as output pins sequentially in accordance with a clock signal, and further configured to use a scan signal to provide different voltages to the output pins and determine states of the switches in accordance with a voltage of the input pin.

10. The switch-scanning circuit of claim 9, wherein the chip further comprises:
a buffer configured to store a high threshold and a low threshold; and
a voltage comparator configured to compare the voltage of the first pin with a reference voltage, and to output a comparison result, wherein the processing unit modifies the reference voltage to the high threshold or the low threshold dynamically.

11. The switch-scanning circuit of claim 10, wherein when the input pin is the first pin, and the output pin which is scanned is the second pin, and the processing unit determines the state of the first switch in accordance with the comparison result from the voltage comparator.

12. The switch-scanning circuit of claim 11, wherein when the voltage of the input pin is higher than the high threshold, the processing unit determines that the first switch is switched off; when the voltage of the input pin is lower than the high threshold and higher than the low threshold, the processing unit determines that the first switch is switched on; and when the voltage of the input pin is lower than the low threshold, the processing unit records the comparison result and the state of the first switch in the buffer.

13. The switch-scanning circuit of claim 10, wherein the high threshold and the low threshold are related to resistances of the resistors.

14. The switch-scanning circuit of claim 10, wherein the resistance values of the resistors are the same, the high threshold is equal to a voltage of the power source minus a range value, and the low threshold is equal to half of the voltage of the power source minus another range value.

15. The switch-scanning circuit of claim 9, wherein the processing unit uses the scan signal to provide a low electrical potential to the output pin which is scanned and a high electrical potential to the rest of the output pins.

16. A switch-scanning method, comprising:
setting one of a plurality of pins as an input pin and the rest of the pins as output pins in accordance with a clock signal;
using a scan signal to provide a low electrical potential to an output pin which is scanned and a high electrical potential to the rest of the output pins, wherein the output pin which is scanned is one of the output pins; and
determining a state of at least one first switch in accordance with a voltage of the input pin, and the at least one first switch is a switch being one of a plurality of switches and located between the input pin and the output pin which is scanned.

17. The switch-scanning method of claim 16, wherein determining the state of the at least one first switch comprises:
comparing the voltage of the input pin with a high threshold and a low threshold, and determining the state of the at least one first switch in accordance with a comparison result.

18. The switch-scanning method of claim 16, wherein determining the state of the at least one first switch comprises:
when the voltage of the input pin is higher than the high threshold, it is determined that the at least one first switch is switched off; when the voltage of the input pin is lower than the high threshold and higher than the low threshold, it is determined that the at least one first switch is switched on; and when the voltage of the input pin is lower than the low threshold, the comparison result and the state of the at least one first switch is recorded in a buffer.

19. The switch-scanning method of claim 16, wherein the high threshold is equal to a voltage of a power source minus a range value, and the low threshold is equal to half of the voltage of the power source minus another range value.
